(19) United States
(12) Patent Application Publication
(10) Pub. No.: US 2015/0068586 A1
(43) Pub. Date: Mar. 12, 2015

(54) Array of Photovoltaic Cells

(71) Applicant: FTL Systems, Inc., Rochester, MN (US)

(72) Inventors: John C. Willis, Rochester, MN (US); Richard G. Munden, Carson City, NV (US); Ruth A. Betcher, Rochester, MN (US); Samad Moini, Alpine, CA (US)

(21) Appl. No.: 14/547,132

(22) Filed: Nov. 19, 2014

Related U.S. Application Data
(62) Division of application No. 13/434,837, filed on Mar. 29, 2012.
(60) Provisional application No. 61/469,031, filed on Mar. 29, 2011.

(51) Int. Cl. H01L 31/054; F03G 6/00; H02S 40/32

(52) U.S. Cl. CPC H01L 31/0543; H02S 40/32; F03G 6/001
USPC 136/246; 136/259; 60/641.8

(57) ABSTRACT

A solar energy harvesting and storage system is disclosed having a dual-sided lithographically integrated light-to-electrical energy converter. The integrated light-to-electrical energy converter has at least one array of photovoltaic, cells having an array of optoelectronic components, each of which have a compound optical structure that spatially separates light into multiple wavelengths and a P/N junction having a gradient of semiconductor materials and/or dopants responsive to a narrow band of wavelengths. A common electrode connects the optoelectronic components and the common electrode is electrically connected to at least one integrated DC to AC inverter. Also disclosed is a dual-axis solar tracking system upon which the dual-sided lithographically integrated light-to-electrical energy converter is mounted. The dual-axis solar tracking system has two stages of tracking mounts, each tracking mount has a plurality of leaf-springs in a vertical arrangement. The leaf springs have differential coefficients of expansion and contraction so that each tracking mount tracks a solar light source in an orthogonal direction from the other tracking mount.

### RELATED APPLICATIONS

This application is a divisional application of pending U.S. patent application Ser. No. 13/434,837 entitled SOLAR ENERGY HARVESTING AND STORAGE SYSTEM filed on 29 Mar. 2012 and claims priority of and is related to U.S. Provisional Application 61/469,031 entitled SOLAR COLLECTOR AND SYSTEM FOR SPATIAL AND SPECTRAL CONCENTRATION OF SOLAR POWER filed on 29 Mar. 2011, having common inventors and a common assignee, which is hereby incorporated by reference in its entirety.

### FIELD OF THE INVENTION

This invention relates generally to field of solar energy and solar collectors and more particularly relates to the efficient spatial and spectral concentration of sunlight throughout daily and seasonal changes.

### BACKGROUND

Communities and individual electrical power users located in cold climates comprise more than twenty-five percent of the North American population. In adverse weather during the months of winter, late fall, early spring months, the availability of electrical power is both a productivity and life-critical requirement and the energy supply chains are vulnerable. Unless long distance power transmission lines are both available and operating, isolated users in northern latitudinal climates depend on fossil fuel generators and stored fuel supplies. Transportation costs for getting fossil fuel into these isolated areas results in high energy costs. Community power organizations and larger end users require installations with continuous average power availability ranging between ten kilowatts for the average single home in the United States in 2006 and ten megawatts representing the legislative limit for many community power distribution cooperatives.

Farmers, small rural communities, local power distribution cooperatives and firms in cold climates have increased regulatory and contractual capability for small-scale, renewable power generation. Industrial and military programs must meet power needs of isolated bases without the dangerous trucking and shipment of high volatility fossil fuels. National Science Foundation (NSF) efforts in Antarctica and comparable places now rely on seasonal fuel deliveries at great expense.

Conventional renewable energy alternatives to fossil fuel generators depend on water flow, wind or solar illumination. Water flow, hydroelectric power, is cost effective when the users are at a reasonable distance from hydro-power generators so that long distance transmission lines are not required. In cold climates, seasonal variations in the sun's angle range nearly ninety degrees from just below the horizon to nearly overhead. A stationary lens with convex optical properties is not able to effectively concentrate light. If wind and solar energy are the primary and not the supplementary source of energy, there is the risk of not being able to meet instantaneous power demands. Wind power, moreover, loses efficiency when scaling down, imposes undesirable noise when sited close to load centers, and takes a toll on avian wildlife, preventing implementation on some migratory routes.

Solar energy using collectors having thin film cells reduce cost but at the expense of efficiency and area required. Techniques for high efficiency solar cells are known in niche industries such as earth-orbiting spacecraft but at significant cost premium.

Communities and electrical power users in cold climates would benefit from solar power systems suited to their climate if the life-cycle cost of continuous power from such renewable sources was cost efficient. Contemporary solar power systems have focused on warm and sunny climates such as the US southwest and Iberia. Such systems lack the conversion efficiency, environmental hardening and long term storage capability needed to provide primary power supply when communities in cold climates most need electrical power.

### SUMMARY

The embodiments of a solar energy harvesting and storage system incorporates a dual-sided solar cell that efficiently harnesses wide swaths of solar bandwidth with a lithographically integrated DC to AC inverter. The embodiments described herein improve on existing solar collectors on: (1) the energy per unit area; (2) the energy per unit cost; (3) long term system durability; and (4) providing integrated wireless data and telephony capability. Energy per unit area is enhanced by harvesting more of the light spectrum and maximizing conversion efficiency for a given wavelength. Many deployment situations have limited land or roof space. Such situations often benefit from generating maximum energy from the available area. Even where land or roof area is abundant, larger deployments consume more structural elements and longer power cables. Even if area is unrestricted, cost seldom is. Greater energy per unit cost is achieved using techniques including concentration of light, use of dual-sided solar cells and making the most efficient use of expensive III/V compounds. Long term durability is enhanced through techniques such as a robust solar tracker, use of dual-sided steel rather than fragile silicon wafers and integration of the solar cell with the DC to AC inverter on a common substrata electrode. The embodiments described herein achieve long term durability and lower cost of operation/maintenance to make solar energy a more attractive energy option.

Integrated wireless and data telephony within the panel assembly both improves long term maintainability and facilitates use of panel assemblies in areas lacking physical infrastructure, time or experienced installers. Such enhanced functionality reduces the barrier to deployment of solar energy.

### DESCRIPTION OF THE DRAWINGS

FIG. 1 is a block diagram of the major components of the solar energy harvesting and storage system as described herein. It is suggested that FIG. 1 be printed on the face of the patent.

FIG. 2 is a block diagram of a direct solar operating mode of the solar energy harvesting and storage system.

FIG. 3 is a block diagram of a supplemented solar operating mode of the solar energy harvesting and storage system.

FIG. 4 is a block diagram of a stored energy solar operating mode of the solar energy harvesting and storage system.

FIG. 5 is a structural diagram of the light-to electrical energy converter in accordance with an embodiment described herein.

FIG. 6 is an illustration of a dual-sided solar cell in accordance with an embodiment described herein.

FIG. 7 describes the flow process of seed layer deposition in the creation of the photovoltaic solar cell in accordance with an embodiment described herein.

FIG. 8 is an illustration of the semiconductor junction structure of the photovoltaic solar cell in accordance with an embodiment described herein.

FIG. 9 is a flow chart of the selection optical fill process.

FIG. 10 is a side view of the solar panel assembly in accordance with an embodiment described herein.

FIG. 11 is an end view of the solar panel assembly in accordance with an embodiment described herein.

FIG. 12 is a plan view of the solar panel assembly in accordance with an embodiment described herein.

FIG. 13 is a block diagram of an integrated DC to AC converter in accordance with an embodiment described herein.

### DETAILED DESCRIPTION

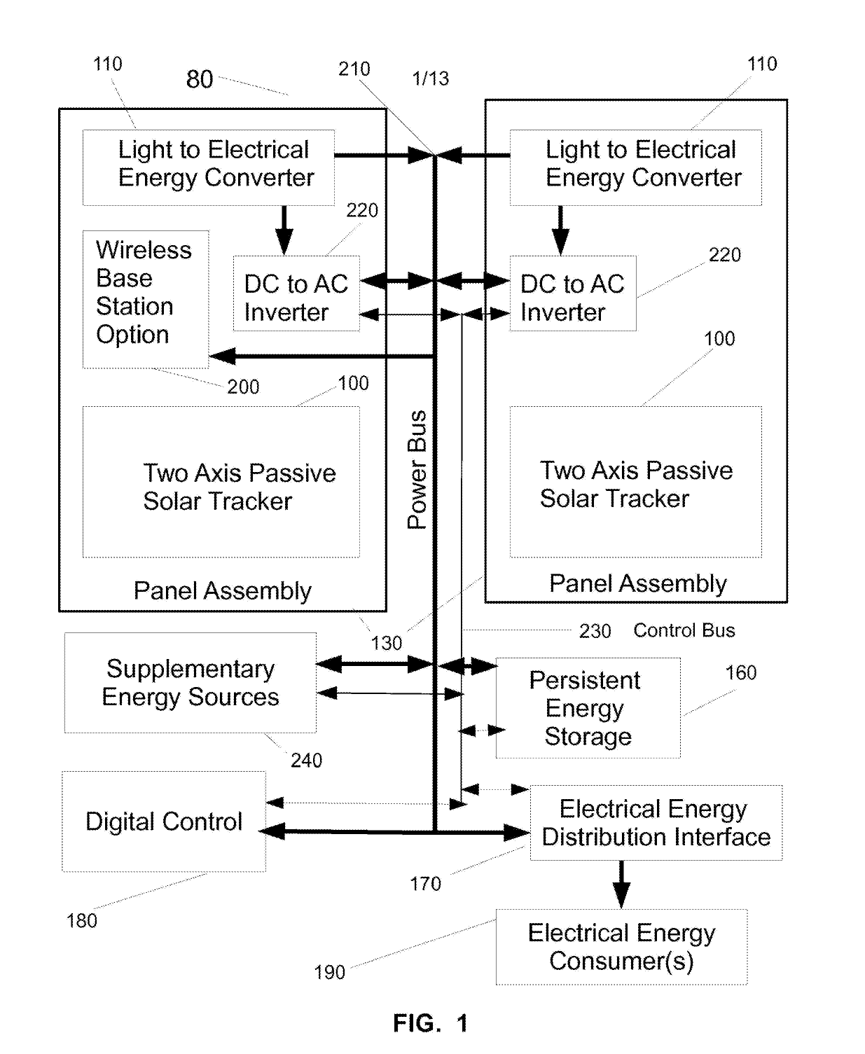

These embodiments will best be understood when viewing the FIGS. along with the detail description provided herewith. With reference to FIG. 1, a block diagram of the architecture of the solar energy harvesting and storage system 80 is shown. The solar energy harvesting and storage system 80 comprises a plurality of solar panel assemblies 130 connected on a power bus 210 to a persistent energy storage 160, supplementary energy sources 240, digital control 180, an electrical energy distribution interface 170 from which power is distributed to electrical energy consumers(s) 190. Digital control 180 is connected to the various components, such as the DC to AC inverters 220, supplementary energy sources 230, persistent energy storage 160, the electrical energy distribution interface 170 through a control bus 230.

Although two panel assemblies 130 are shown, preferably there are more panel assemblies, up to hundreds or more, in the solar energy harvesting and storage system 80. Each panel assembly 130 comprises a light-to-electrical energy converter 110 connected to the power bus 210 and to a DC to AC inverter 220, also connected to the power bus 210 and the control bus 230. The panel assembly 130 may also have a wireless base station 200, also connected to the power bus 210. The light-to-electrical energy converter 110, the DC to AC inverter 220 and the wireless base station 200 are mounted on a two axis passive solar tracker 100.

Persistent energy storage 160 retains energy during periods where limited solar illumination does not provide sufficient energy from the light-to-electrical energy converter 110. Numerous forms of chemical (battery) and thermal storage are known. However most economical alternatives reported in the literature or in common commercial use suffer from use of expensive, hazardous materials as well as leakage. Leakage reduces the energy stored over time. Current adequate design options for the persistent energy storage exist, but are suboptimal.

Supplementary energy sources 240 are included to reduce dependence on persistent energy storage 160. Examples of supplementary energy sources 240 include wind, geothermal, hydro and even conventional sources such as fossil fuel or nuclear. Hybrid installations may share components such as the persistent energy store 160, DC to AC inverter 220, electrical energy distribution interface 170 and transmission line assets.

The electrical energy distribution interface 170 attaches energy generated by the solar energy harvesting and storage system 80 to local or national scale power grids. The electrical energy distribution interface 170 insures that voltage, frequency and phase of the solar power matches that of the power distribution system; local generation and grid power are isolated from one another; and that the relative flow of energy may be measured and reported for economic reasons. Techniques for implementing such an electrical energy distribution are well understood, commercially available from many vendors and already installed in numerous installations ranging from local fossil fuel generators to alternative energy production facilities.

Digital control 180 is required to coordinate and implement functionality among the components of the solar energy harvesting and storage system 80. Among the functions of digital control 180 are: consistent maintenance of voltage, frequency and phase; ensuring adequate power source; recognition of developing failures and reporting for timely maintenance; partitioning of failed components from the power bus 210 and control bus 230 and economic analysis and reporting. The digital control system 180 is commonly implemented in many situations for industrial control. A wireless control link that could be primary or a backup, requires a wireless base station 200 within the digital control 180.

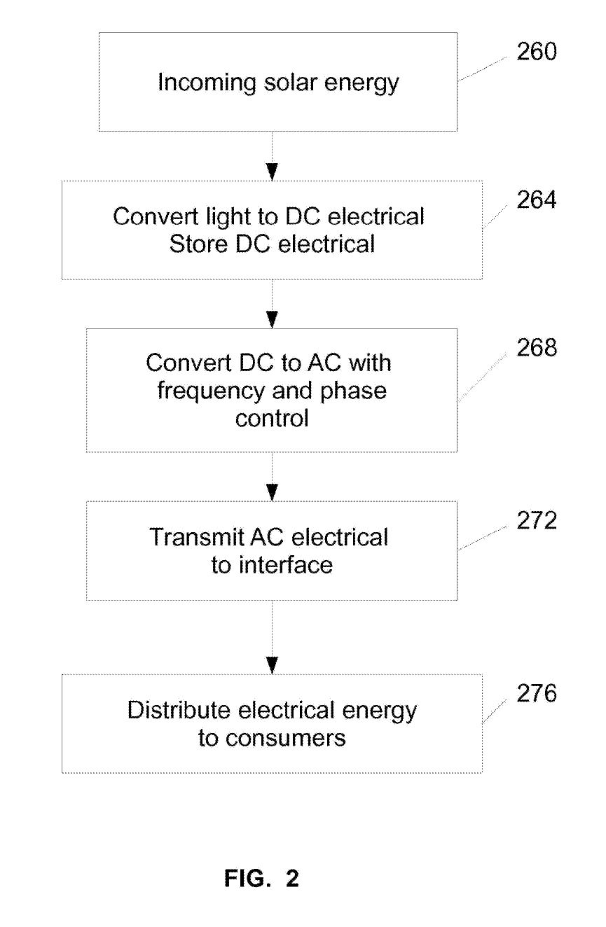

The solar energy harvesting and storage system 80 has at least three operating modes, whose block diagrams are shown in FIGS. 2-4. In a direct solar operating mode shown in FIG. 2, incident solar energy is received in the light to electrical energy converter 110, as shown in block 260. In block 264, the photons of the solar energy are converted to electrical energy as direct current within the light to electrical energy converter 110. The generated DC energy can be transmitted directly over the power bus 210 and stored in persistent energy storage 160. In addition, the integrated DC to AC inverter 220 converts the direct current energy into alternating current at a voltage, frequency and phase set in the digital control 180 and transmitted on the control bus 230, as shown in block 268. In block 272, the AC electrical energy is transmitted over the power bus 210 to an electrical energy distribution interface 170. In block 276, the electrical energy is distributed through the electrical energy distribution interface 170 to energy consumers 190.

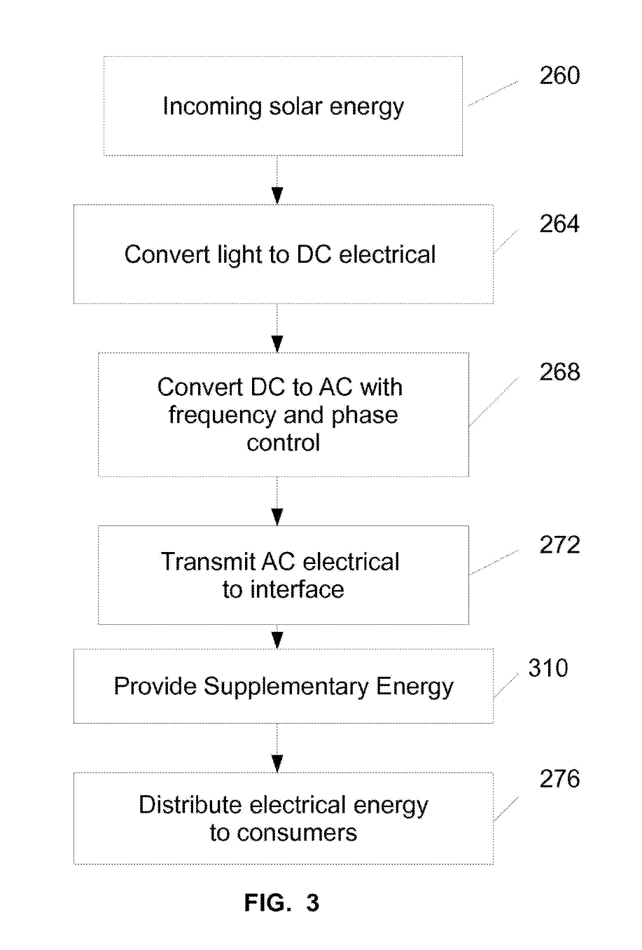

An additional operating mode of the solar energy harvesting and storage system 80 is shown in FIG. 3. In the supplemented solar operating mode shown in FIG. 3, incident solar energy is received in the light to electrical energy converter 110, as shown in block 260. In block 264, the photons of the solar energy are converted to electrical energy as direct current within the light to electrical energy converter 110. The generated DC energy can be transmitted directly over the power bus 210 and stored in persistent energy storage 160. The integrated DC to AC inverter 220 converts the direct current energy into alternating current at a voltage, frequency and phase set in the digital control 180 and transmitted on the control bus 230, as shown in block 268. In block 272, the AC electrical energy is transmitted over the power bus 210 to an electrical energy distribution interface 170. If necessary or desired, supplemental energy from either the persistent energy storage 170 and/or from the supplementary energy sources 240 are also combined with the AC electrical energy output from the DC to AC inverters 220 to maintain a desired voltage, frequency and phase determined by the digital control 180. As in other operating modes, in block 276, the electrical energy is distributed through the electrical energy distribution interface 170 to energy consumers 190.

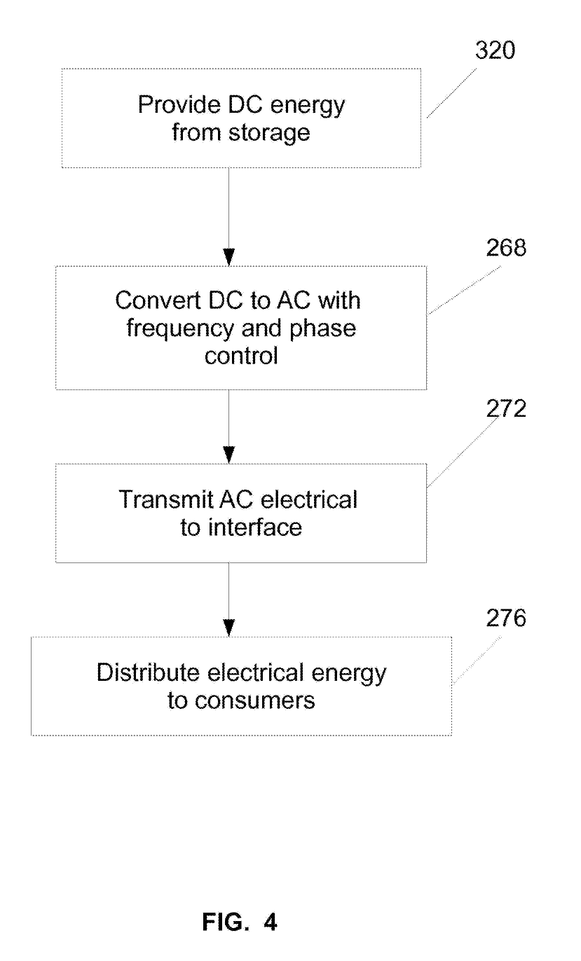

FIG. 4 is a block diagram of the stored energy operating mode of the solar energy harvesting and storage system 80. Block 320 shows that direct current energy is supplied from the persistent energy storage 160 and/or the supplementary energy sources 240. The DC to AC inverter 220 converts the direct current energy into alternating current at a voltage, frequency and phase set in the digital control 180 and transmitted on the control bus 230, as shown in block 268. In block 272, the AC electrical energy is transmitted over the power bus 210 to an electrical energy distribution interface 170. As in other operating modes, in block 276, the electrical energy is distributed through the electrical energy distribution interface 170 to energy consumers 190.

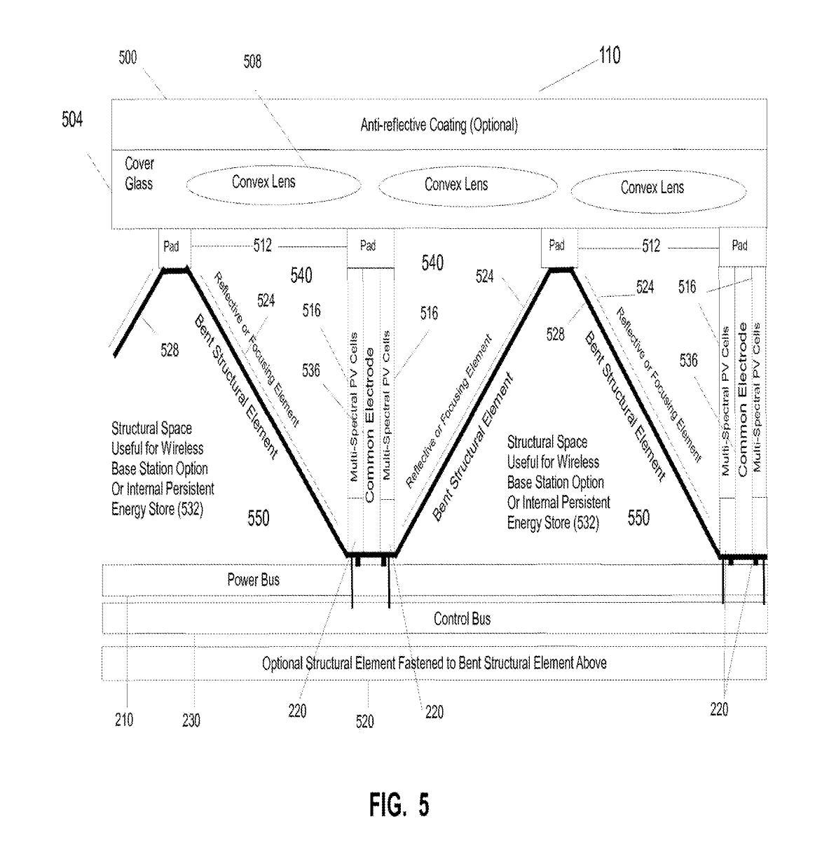

FIG. 5 is a structural diagram of the light-to-electrical energy converter 110. The light-to-electrical energy converter 110 receives incident sunlight, concentrates the solar energy and then focuses the solar energy onto a photovoltaic cell for conversion to DC energy. Within a sealed housing (not shown) of aluminum, steel, plastic, or other rigid and durable material is a bent or angular “corrugated” zig-zag structural element 528 forming spaces above 540 and spaces below 550 the bent structural element 528. The bent structural element 528 may be metal, resin, and other materials sufficient to provide rigid support in varying weather and light conditions. Extending normal or near normal from a planar surface at the troughs of the bent structural element 528 and bisecting the upper space is an arrangement of a plurality of photovoltaic cells 516 electrically connected via a common electrode 535 to another similar arrangement of photovoltaic cells 516. In typical solar cell construction the silicon substrata represents a significant cost element. Replacing silicon wafers with a common electrode 536 enables both use of a potentially less expensive substrata and doubling area coverage of the substrata or common electrode 536.

At the crests of the bent structural element 528 are pads 512 to eliminate or reduce vibration and mechanical stresses on the bent structural element 528. The light-to-electrical energy converter 110 can be assembled in at least three configurations. As a first configuration, the photovoltaic cells 515 are assembled on both sides of the common electrode 536 as shown. A second configuration having two single-sided cells simplifies manufacture. A third configuration is that the photovoltaic element 516 is formed on a single side of a conventional wafer using traditional solar cell mounting technology.

Mounted in the housing and positioned on the pads 512 is a cover glass 504 having an optional plurality of convex lenses 508 that are spaced with respect to each other and positioned above the bent structural element 528 to focus light onto a reflective or focusing element 524 on the angular sides of the bent structural element 528. The convex lenses 508 can be formed by masking, etching, molding or grinding. Light received through the convex lenses 508 is directed to the reflective or focusing element 528 that receives and concentrates the light. The cover glass 504 or other suitable material is selected to have good optical transmission properties throughout the widest range of frequencies at which the sun emits optical and near-optical radiation. An anti-reflective coating 500 may be applied to the cover glass 504. Similarly, an anti-reflective coating, if applied, should have similar optical qualities and may be applied to the cover glass 504 by deposition techniques. In one embodiment, microphotoetched metals can be used instead of a holographic anti-reflective film. In another instance, neither existing wafer technology nor thin films are used.

Use of a double-sided common electrode 536 as shown, however, requires introduction of a reflective or focusing element 524. There are many different ways to fabricate the reflective or focusing element 524. Glass mirrors, although very stable, tend to be fragile and are subject to degradation of the reflective material. Various plastic materials are more robust to physical stress, weigh less but are more subject to degradation over time. When the bent structural element 528 is metallic, forming a grating directly in the structural element 528 reduces material and assembly cost while having the potential for high durability. Filling the solar energy producing void 540 with an inert gas such as nitrogen further reduces degradation of the reflective surface. In addition, plating material may be applied over the reflective or focusing element 524 to inhibit oxidation and retain high reflectivity over time. The reflective or focusing element 524 can either be used directly as a mirror or ruled to construct a grating that will focus as well as reflect the incident light. By focusing the light, the area covered by the photovoltaic cells 516 is reduced. The increased optical concentration, however, also increases heating. Excess heat can degrade the photovoltaic cells 516 or the DC to AC inverters 220 over time.

The spaces 540 above the bent structural element 528 into which the reflective or focusing element 524 and the photovoltaic cells 516 extend may be filled with an inert gas such as dry nitrogen to minimize condensation, corrosion and other degeneration; The spaces 550 below the bent structural element 528 towards the power bus 210 may be void or may be filled other matter useful for wireless base station operation or internal persistent energy storage 532.

Integrated with the array of photovoltaic cells 650 and the common electrode 536 are DC to AC inverters 220 to convert the DC electrical energy generated by the photovoltaic cells 650 into AC energy. The DC to AC inverters 220 connected to the photovoltaic cells 650 provide control and distributed DC to AC conversion to a high frequency multiple of the line frequency and carefully controlled phase. Incorporating DC to AC inverters 220 directly into the photovoltaic cells 650 provides advantages. Because the inverters 220 are distributed throughout the installation, concentrated heat and low-frequency noise generated as with conventional inverters are prevented—an important safety feature, especially in close proximity to human-occupied areas, flammable ground cover or roofing material. The distributed DC to AC inverters 220 yield alternating current output at voltage levels consistent with semiconductor device voltages and frequencies that are a multiple of and in-phase with the power distribution frequencies of the power grids.

The DC to AC inverters 220 are also electrically connected to the power bus 210 and to the control bus 230. The common electrode 516 which extends upward from the trough of the bent structural element 528 is electrically connected to power bus 210 for the transmission of DC electrical energy generated by the photovoltaic cells 516. Control bus 230 is also electrically connected to the light-to-electrical energy converter 110 and/or the internal persistent energy store 160.

Circuit technology for implementing various kinds of DC to AC inverters is known in the literature. Conventional switching regulators, producing a square wave, are efficient and easily implemented but are incompatible with some kinds of equipment using electrical energy. Sine wave and modified sine wave converters are more complex but increasingly required for unrestricted end use compatibility.

Innovatively, the DC to AC inverters 220 are lithographically formed directly on the same substrata as the photovoltaic cells 516. Techniques for lithographically forming resistors, small capacitors, inductors and transistors are well known and commonly implemented by industry, such as monolithic point of load regulators offered by firms such as National Semiconductor and Linear Devices. Integrating the photovoltaic cells 516 with the DC and AC inverters 220 requires additional processing layers but reduces the assembly required, reduces cost and most importantly eliminates solder or other junctions between the common electrode and discrete devices. Large capacitors, insulators and comparable components are also major sources of failure eliminated by this integrative approach. By distributing the DC to AC inverters 220 throughout the array, heat from the inverters helps to melt snow and ice which may otherwise form on the anti-reflective coating during periods when limited solar illumination allows surface temperature to drop.

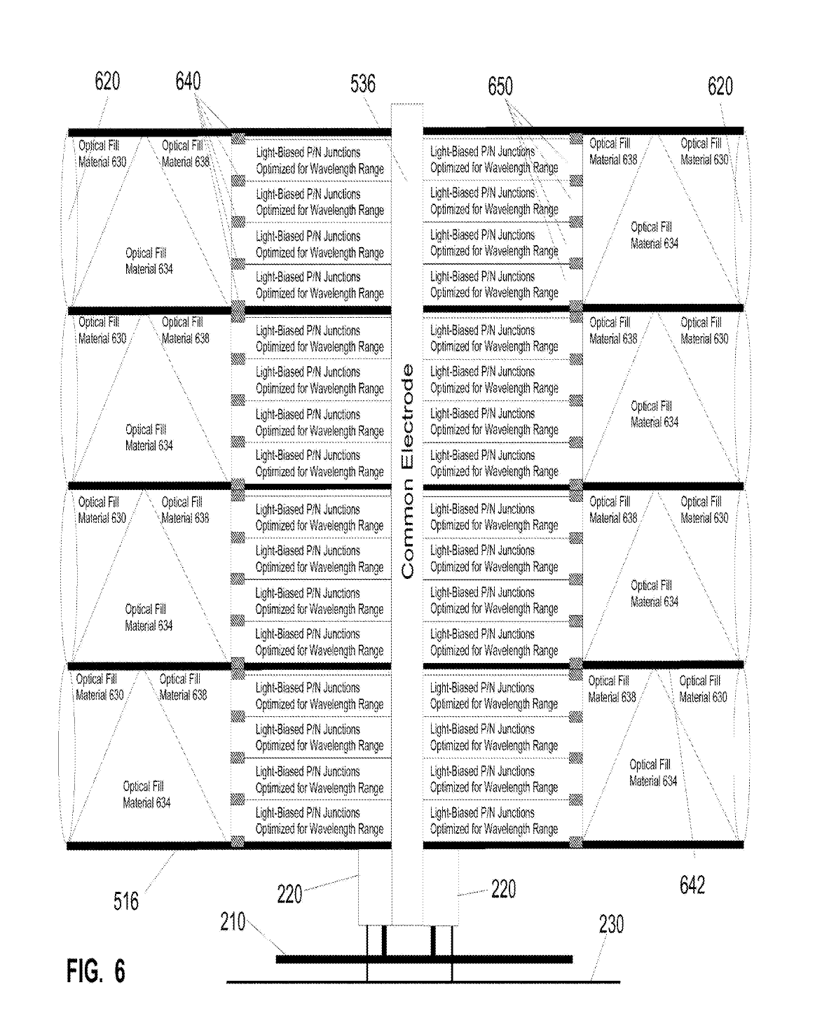

FIG. 6 is a structural diagram of the photovoltaic cells 516 of the light to electrical energy converter 110. Light reflected from the reflective or focusing element 524 is incident upon the arrangement of photovoltaic cells 516. Eight photovoltaic cells 516 are illustrated but in actuality tens, hundreds, or thousands photovoltaic cells can be robotically manufactured to obtain efficiencies of scale and wired in series/parallel with isolating switches. Although illustrated as two linear arrays each having four photovoltaic cells 650, the photovoltaic cells 650 may be arranged in a two-dimensional array, preferably of up to 256 or more photovoltaic cells per array. Each photovoltaic cell 516 has a convex lens 620 on the order of approximately one centimeter to focus incoming light toward a central optical axis of each photovoltaic cell 516. Between the convex lens 620 and the optoelectronic junctions 650 are at least two or more different optical materials 630, 634, 638 wherein at least the outer optical materials 630, 638 have a different index of refraction relative to the second material 634. This arrangement of the optical fill materials 630, 634, 638 creates a compound optical structure that spatially segregates light into a plurality of different wavelengths both across the illustrated plane and in/out of the plane along central axis of the convex lens. In certain circumstances, it may be preferable that each optical fill material 630, 634, 638 have a unique index of refraction to achieve the desired separation of wavelengths. Both the indices of refraction of the optical fill material 630, 634, 638 and the orientation of the optical fill material 630, 634, 638 determine wavelength separation, an important feature of the photovoltaic cell 517; these parameters can be adjusted to achieve a desired result, for example as in separating infrared from visible from ultraviolet wavelengths. Critically, the junctions and the wavelength divisions are formed using integral lithographic techniques. The walls 642 of the cells 516 provide a containment space to deposit and shape the optical fill material 630, 634, 638 as well as to accommodate thermal expansion allowing the array of photovoltaic cells 516 to match thermal expansion/contraction of the common electrode 537 and the other components. Optical fill material 630, 634, 638 may be, for example, optical grade silicon, a clear thermoplastic resin, or other material that is transparent and has a high strength, rigidity, is preferably electrically insulating, and has compatible thermal expansion and contraction characteristics.

Each photovoltaic cell 516 further comprises a matrix of wavelength-specific light biased junctions 650 with band-gaps matching frequencies of the incident wavelengths on that cell 516. Each opto-electronic junction is on the order one millimeter. These optoelectronic junctions 650 receive the spatially separated optical output from the optical fill material 638 and convert the optical energy to electrical energy. Thus, particular ones of the opto-electronic junctions 650 are more responsive to particular wavelengths, depending upon the choice of materials comprising the opto-electronic junctions 650, for instance Type III/V semiconductor materials are responsive to different wavelengths than silicon or Type II/VI semiconductor materials. The bandgap relative concentrations of the dopants in the semiconductor material making up the opto-electronic junction 650 changes the output voltage and the conversion efficiency at a particular wavelength. Preferably, the wavelength-specific light-based opto-electronic junctions 650 comprise a P/N semiconductor junction, preferably a Group III/V composition and more preferably indium phosphide, for high bandwidth data transmission using very narrow band, coherent optical radiation. A plurality of electrodes 640 provide for a current path to the common electrode 536.

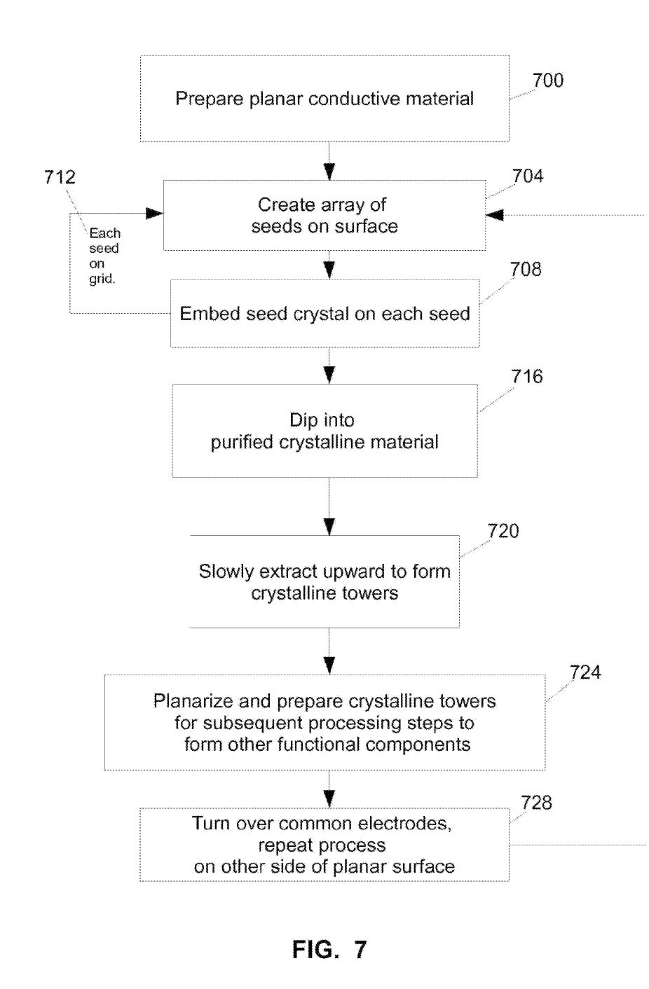

FIG. 7 presents the process by which the common electrode 536 is prepared for the formation of the opto-electronic components 650, surface electrodes and other electrodes 640, optical fill material 630, 634, 638, DC to AC inverters 220 and other components integrated with or otherwise attached to the common electrode 536. In block 700, a planar conductive material, such as steel or copper or other supportive conductive material to be used as the common electrode 536 is cleaned, de-oxidized and cut to a required size for the number of photovoltaic cells 516 to be formed. The size will typically be rectangular or a narrow strip for continuous handling and manipulation. At step 704, one surface of the planar conductive material is scanned, preferably with a laser beam having sufficient energy to briefly melt seed-size points in a two-dimensional grid array and further creating markers to align masks and other subsequent processing stages. In steps 708-712, as each seed-size point in the raster is melted, a seed crystal of, e.g., purified silicon or other semiconductor growth material suitable for the formation of the opto-electronic junction is applied to each seed site and embedded onto the planar conductive surface.

To begin the formation of the opto-electronic junction 650, in step 716, the planar conductive material, also referred to as the common electrode 536, is inserted with the seeded surface facing downward into a crucible. The crucible contains a purified crystalline material in a liquid, gaseous or other comparable phase that is also compatible with the seed crystal applied in step 708. In block 720, the common electrode 536 is slowly extracted upwards from the crucible to form crystalline towers descending from each seed crystal. This step closely resembles the extraction of a seed crystal to form crystal ingots used in semiconductor wafer production; microscale equivalents of crystal pulling techniques enable formation of the base material for the wavelength-specific light biased opto-electronic junctions 650.

In step 724, the crystalline towers are planarized and otherwise prepared for subsequent processing steps to form the opto-electronic junctions 650, the surface electrodes 640, the optical fill material 630, 634, 638, the DC to AC inverter circuits 220 and/or other interconnects to the power bus 210 and the control bus 230, or other connections and components. In step 728, the common electrodes are turned over once to repeat steps 704 through 724 to form similar crystalline towers on the other surfaces of the planar conductive material.

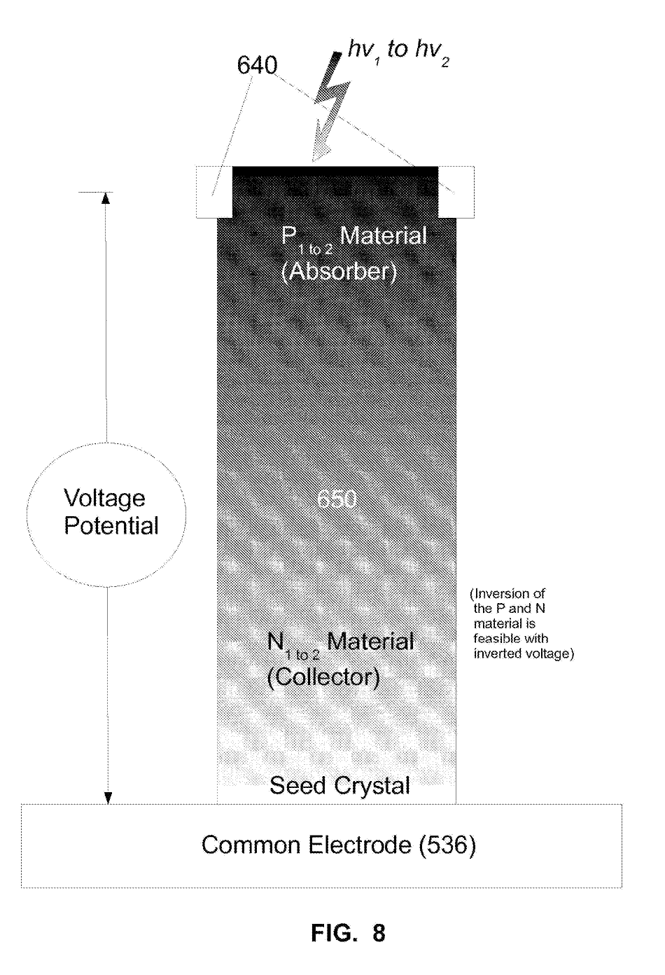

FIG. 8 is an illustration of the opto-electronic junction 650 used in accordance with an embodiment described herein. Using fabrication resist and deposition techniques the various band-gap materials may be grown onto the seed crystal formed above so that the opto-electronic junction has the appropriate sensitivity of wavelength bands, v₁ to v₂. From the common electrode 536, the semiconductor material is grown and doped from a high N dopant concentration to a high P dopant concentration. As mentioned, the material bandgap concentration of the different dopants affect the conversion efficiency and the voltage obtained from the junction at a particular wavelength. The sensitivity to the wavelengths is determined the type of semiconductor materials used, e.g., whether silicon, Type III/V, Type II/VI, etc, and by the spatial distribution of the wavelengths determined by the indices of refraction and the orientation of the optical fill material, as will be described. The relationship between the wavelengths and the bandgaps of the semiconductor materials of the opto-electronic junction is indicated by the subscripts v₁ to v₂, P_{1 to 2} and N_{1 to 2}. A voltage potential in applied between the surface electrodes 640 and the common electrode 536. Incident light onto the opto-electronic junction is absorbed by the high concentration P dopant and is converted to DC electrical energy collected by the high concentration N dopants. Inversion of the P and the N dopant semiconductor materials is possible with an inverted voltage.

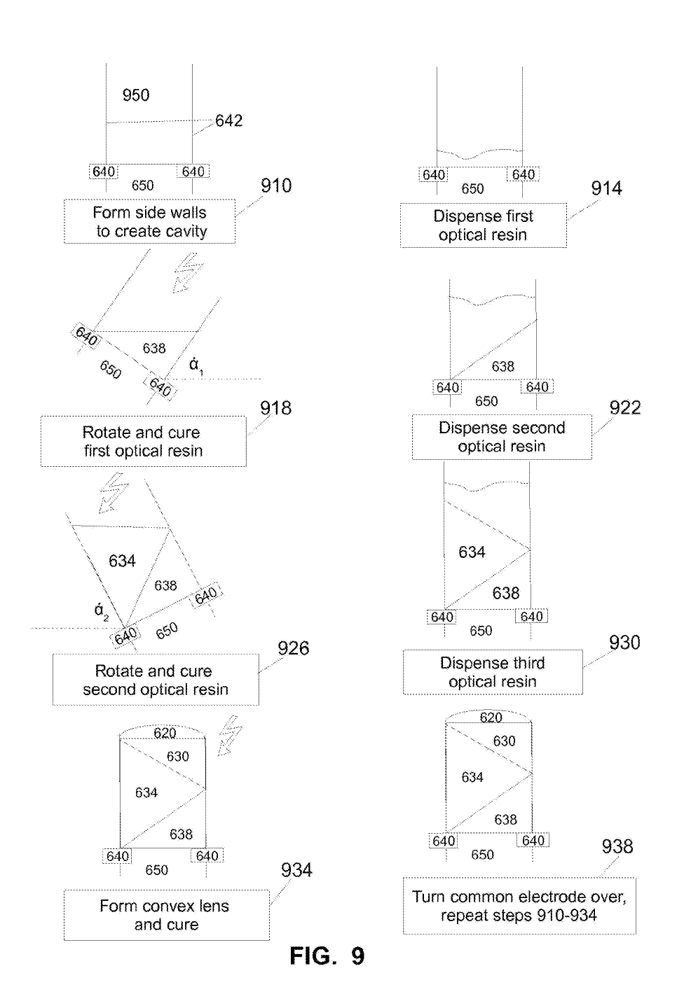

FIG. 9 is an illustration of the process steps by which the compound optical structures of the photovoltaic cells 516 are formed. After the opto-electronic junctions 650 and the surface electrodes 640 have been fabricated and planarized, in step 910 side walls 642 are fabricated using microelectromechanical system (MEMS) techniques to form a cavity 950. Side walls 642 are preferably manufactured from a material that is opaque and nonconductive and of sufficient rigidity to contain the optical material 630-638. In step 914 a first optical resin having a first index of refraction is dispensed into cell cavity 950 at the bottom towards the opto-electronic junction 650. In step 918, the common electrode assembly is rotated at a first angle α₁, perhaps 45 degrees, and the first optical resin is cured by heat, light, radio frequency or other curing means to form the optical fill material 638. In step 922, a second optical resin having a second index of refraction is dispensed into the cavity 950 onto the cured first optical resin. The common electrode assembly is rotated to a second at a second angle, perhaps α₂, perhaps −45 degrees, and the second optical resin is thermally, optically or otherwise cured to form the optical fill material 634, as shown in step 926. In step 930, a third optical resin is dispensed into the cavity 950 on top of the cured optical fill material 634. The third optical resin may be the same as the first optical resin or it may have a different index of refraction as required to spatially separate the incident light. In step 934, a suitable fourth optical resin is applied onto the third optical resin to form a convex lens 920. The differences in viscosity, pressure, density will help to keep the third and fourth optical resins distinct. The third and fourth optical resins are appropriately cured by heat, light, ultraviolet radiation, radio frequencies, or other means to form optical fill material 630 and convex lens 620. Alternatively, convex lens 620 may be formed separately to achieve refractive indices differentiation for the desired wavelength dispersion. Thus, a compound optical structure can be formed on the common electrode 536 for the capture of radiant energy and separation of wavelengths. While the first and second rotated angles α₁ and α₂ are shown and described at 45 and −45 degrees, respectively, the optical fill materials 638, 634, 630 may be rotated at different angles to create the compound optical structure and each optical fill material may have a unique index of refraction.

In step 938 of FIG. 9, the common electrode 536 is flipped or turned over to process the other side having the opto-electronic junctions 650 and common electrodes 640 according to steps 910 through 934. Thus, the integrated light-to-electrical energy converter 110 is manufactured. This light-to-electrical energy converter is then able to receive light, spatially separate the wavelengths. The light output from the compound optical structure is incident upon the opto-electronic junctions 650 that have been doped for efficiently converting photons at a particular range of wavelengths to electrons and a DC current.

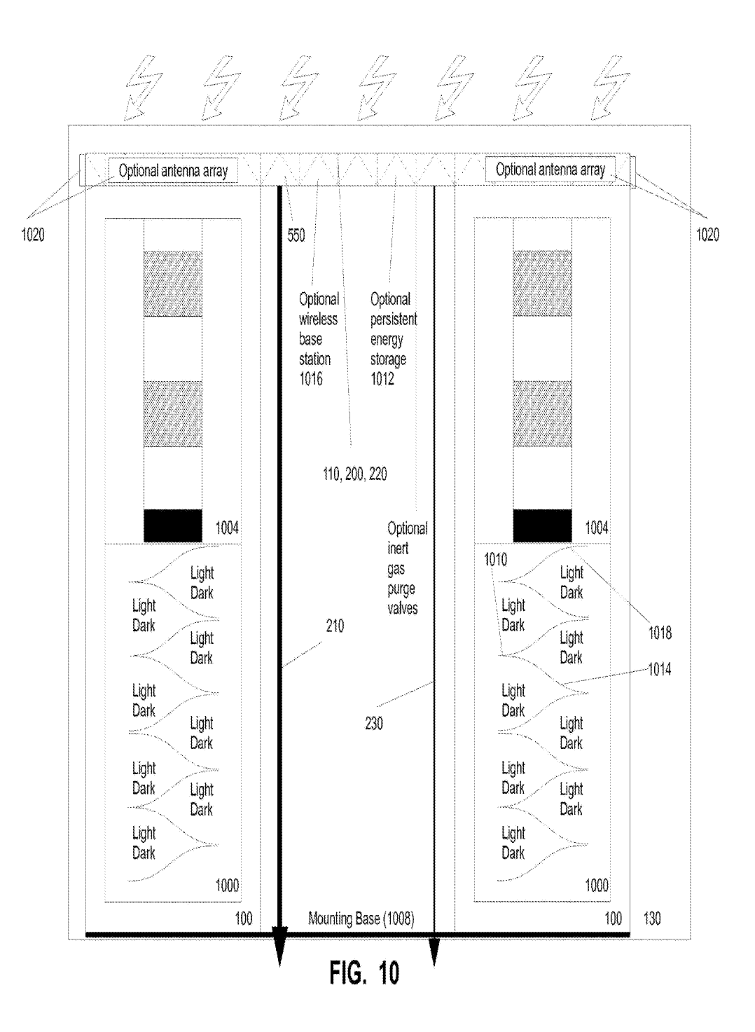

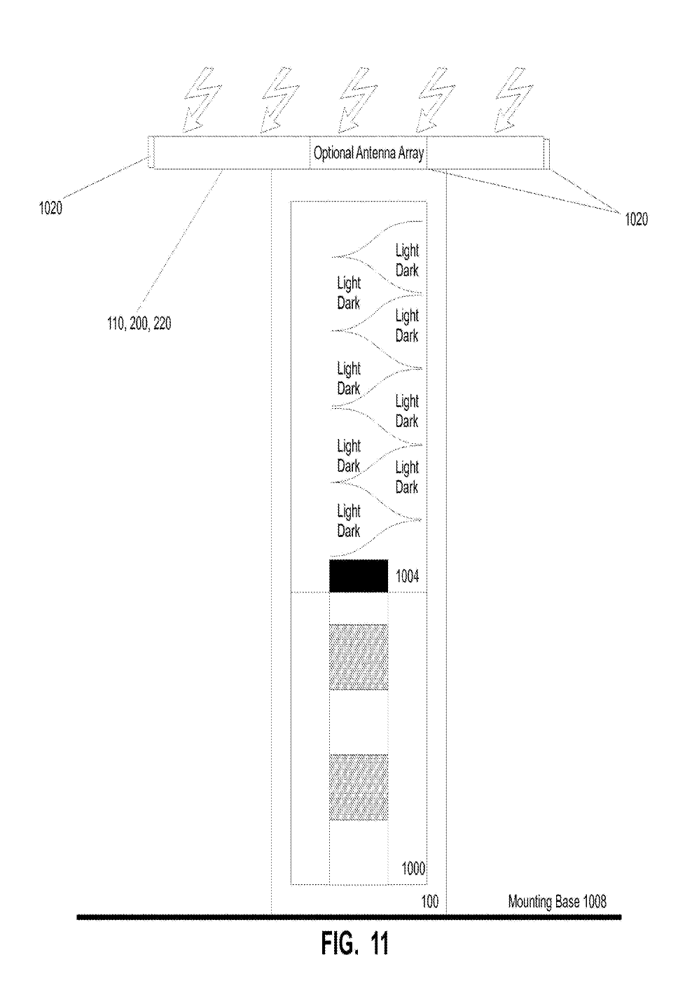

FIGS. 10 and 11 are a side view and an end view of panel assemblies 130 (shown in FIG. 1) showing the light-to-electrical energy converter assembly 110 mounted on a dual axis passive solar tracker 100. FIG. 10 illustrates an optional antenna array 1020 affixed or otherwise mounted onto the panel assembly 130. Voids 550 of the light-to-electrical energy converter assembly 110 may have an optional persistent energy storage, such as a battery, and/or may have additional electronic or mechanical components of an optional wireless base station 200 in communication with the optional antenna array 1020.

The light-to-energy converter assembly 110, the DC to AC inverters 220, and other optional components such as the wireless base station 200, an antenna array 1020, and any matter or components within the space 550 are mounted on a dual axis tracking mount 100 comprising a lower leaf-spring assembly 1000 and an upper leaf-spring assembly 1004. The upper leaf-spring assembly 1004 is mounted on and horizontally rotated ninety degrees from the lower leaf-spring assembly 1000. FIG. 10 illustrates the panel assembly 130 wherein the lower leaf-spring assembly 1000 and the spaces between the leaf-springs 1010 are visible to the reader whereas FIG. 11 illustrates the rotation wherein the upper leaf-spring assembly 1004 and the spaces between the leaf-springs 1010 face the reader. Leaf-springs 1010 are made from steel or other rigid material that can be shaped to provide an elastic spring effect. Leaf-springs 1010 are each approximately ten to twenty centimeters in length and are bent as shown for spring action. The upper side 1014, i.e., the face of the leaf-spring facing upwards, of each leaf spring 1010 has an energy absorptive coating or is made from a material that absorbs solar energy and thus expands while the underside 1018, i.e., the face of each leaf spring facing downwards, has a reflective surface applied with a coating or other material and will contract or expand less than the upper side 1014. Alternatively, the upper side 1014 of the leaf-spring 1010 may be made from a different metal or material having a different coefficient of thermal expansion from the underside 1018 of each leaf spring 1010. The distance between the upper side 1014 to the underside 1018 of each leaf spring 1010 is on the order of five to ten centimeters. The dual axis tracking mount 100 thus steers the solar panel assembly 130 to track solar illumination.

The dual-axis tracking mounts 1000 and 1004 of the panel assembly 130 are able to withstand 130 rotational stress, such as tornadic winds and active loading with lift. Electrical damage from lightening can be minimized with careful site placement. In addition, the mounting base 1008 may be pliant to respond to extreme wind loading as well as provide a high current path for lightening discharge.

The solar concentrator and storage system 100 should preferably be incorporated in the initial design or an extensive refit of the entire roof system when installed on a roof to minimize damage and potential liability. Placing the solar concentrator and storage system 100 at ground level reduces the potential for damage resulting from lightening strikes.

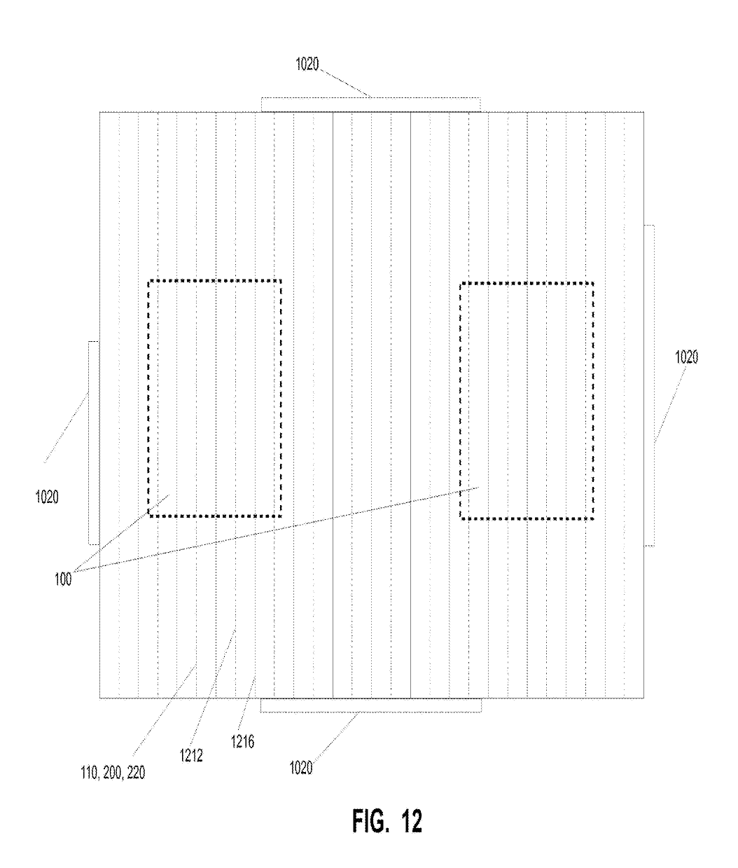

FIG. 12 is a plan view of a panel assembly 130. The features of FIG. 12 are not drawn to scale but are shown to generally illustrate the final assembly of the panel 130. Generally, the dimensions of the panel assembly 130 along the short edges of the paper are on the order of one to two meters and the dimensions of the panel assembly 130 along the long edges of the paper are on the order of two to three meters. Of course, the panel assembly may be larger or smaller; these dimensions are chosen for maneuverability and ease of handling. The two-axis passive solar tracking mounts 100 of the leaf-springs are illustrated underneath the panel assemblies. Preferably, there are two such two-axis passive solar tracking mounts 100 per panel assembly 130 of this size for rotational integrity and to prevent one tracking mount 100 from blocking the light path of another tracking mount 100. Positioned along the periphery of the panel assembly 130 are the optional antenna arrays 1020. The dotted lines 1212 indicate the troughs of the bent structural element 528 (shown in FIG. 5) having the active components of the light-to-electrical energy converter 110, the DC to AC inverters 220 while the sold lines 1216 of the panel assembly 130 represent the crests of the bent structural element 528 (shown in FIG. 5.) having the pads 512 for vibration, shock and mechanical force absorption.

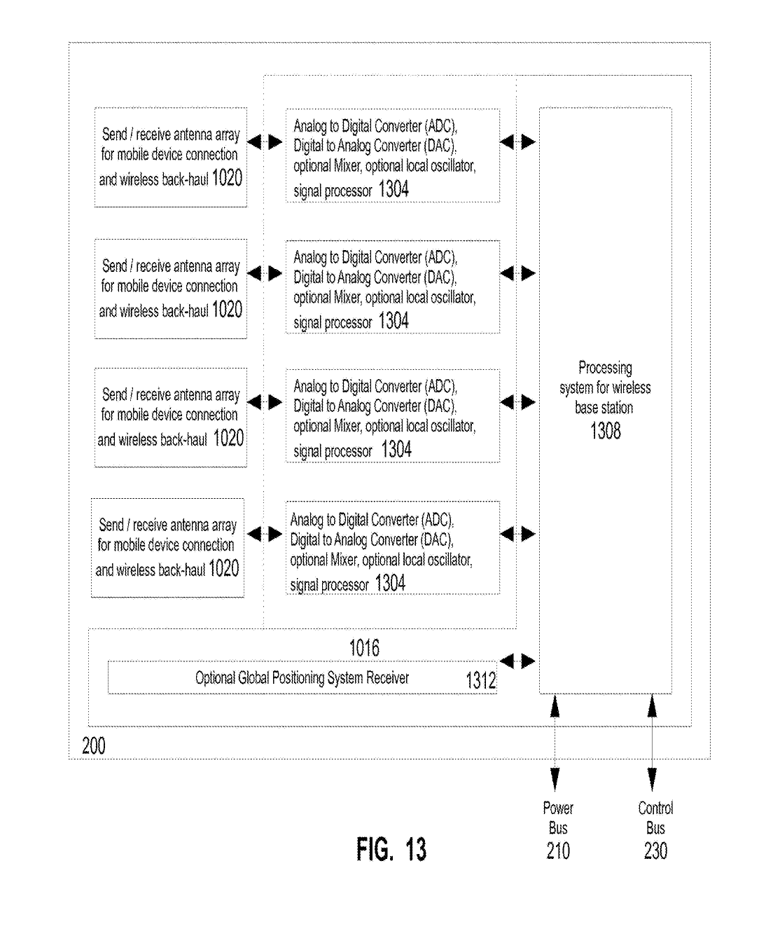

FIG. 13 provides a block diagram of the optional integration of the panel assembly 130 and the wireless base station 200. First the wireless base station 200 integration into the panel assembly 130 provides either a static alternative to or a backup for the control bus 230 in the event that control bus 230 not operational. Integration of the wireless base station 200 having a global position receiver powered by the solar energy harvesting and storage system 80 described herein is particularly useful where installing power lines and wired signal connections to land-based data lines is undesirable or impractical. Examples include isolated rural areas, frozen ground, flooded ground, disasters or situations where trained installers are unavailable.

FIG. 13 illustrates the wireless base station option 200. Functionality in FIG. 13 must be split between antenna arrays 1020 located on the periphery of the panel assembly 130 and a wireless base station 200 located in or shared between components within the void 550 under bent structural element 528 and/or a module situated under the mounting base 1008 of the panel assembly 130. Note that in FIG. 12, there are four antenna arrays 1020 in each directional orientation at the periphery of the panel assembly 130; thus each of the four antenna arrays 1020 is in communication with a wireless base station 200. In a given panel assembly 130, then, there need only be an equivalent number of wireless base stations 200 as the number of antenna arrays 1020.

Antenna arrays 1020 serve not only to connect with wireless edge devices such as smart phones and wireless enabled laptops but also to provide back-haul connections routing to and from the wireless base stations 200 to other such stations within relay range, cell towers or comparable routing infrastructure. Digital beam forming and other techniques for improving signal strength are well known in the wireless design community.

The wireless base station 200 may either operate at carrier frequencies supporting a wide range of protocols or may mix the wireless carrier frequencies down to base band using additional mixer and local oscillator components in the wireless base station 200, as shown in block 1304 of FIG. 13. The former technique is commonly known as software defined radio. Either approach uses analog to digital converters and digital to analog converters, also shown in block 1304, to convert incoming and outgoing signals suitable for both a signal processor in block 1304 to, e.g., demodulate the signals, and a processing system, block 1308, at the heart of the wireless base station 200. Both the signal processor of block 1304 and the processing system of block 1308 are included as part of the wireless base station 200.

Because the panel assembly 130 may be rapidly installed, perhaps by unskilled personnel, it is useful to include an optional global positioning system (GPS) 1312 with the wireless base station 200. This GPS system 1312 is also useful to locate particular panel assemblies 130 during field support. Maintenance operations can be paired with panel health indications to direct field support directly to the right panel assembly. An antenna for the GPS 1312 may be included in one or more of the antenna arrays 1020 for improved signal handling.

Within the panel assembly 130 wired connectivity is provided among the optional antenna array elements 1020 and the signal processing function 1304 and the processing system 1308 of the wireless base station 200. These may most conveniently be located underneath the solar panel assemblies 130 as part of the control bus 230 internal to the panel assembly 130. Power may be derived using AC or DC energy from the power bus 210.

Wireless base stations 200 may be included in some panel assemblies 130 and not others. However this innovative synergy greatly facilitates maintenance, asset tracking as well as providing enhanced wireless communication for other purposes such as data links and telephony. Cost of lower powered base stations such as femtocells makes such integration economically affordable in an increasing application range.

The particular embodiment described herein of the panel assemblies 130 mounted on the dual-axis passive solar tracker 100 satisfies reliability criteria for tracking operations up to twenty-five years in very inclement snow and ice-covering environments and minimal preventative/incident repair. The entire solar collector and storage system 80 has a reliable operation, can be maintained by unskilled workers, and satisfies tight environmental requirements associated with long term operation in close proximity to populated structures. Similarly, during seasons having less than ideal illumination, maximum energy from the sun's daily cycle from sunrise to sunset can be obtained.

Such solar collector and energy storage systems as provided herein can provide power for high performance computer systems, e.g., ranging up to four megawatts each, in such locations and circumstances where there is limited available power and processor power efficiency.

1. A solar energy harvesting and storage system, comprising:
a dual-sided lithographically integrated light-to-electrical energy converter having a dual-sided photovoltaic cell, a compound optical structure; and
a plurality of integrated DC to AC converters.

2. A dual-axis solar tracking system, comprising:
two stages of tracking mounts, each tracking mount comprising a plurality of leafsprings in a vertical arrangement, the leaf springs having differential coefficients of expansion and contraction wherein each tracking mount tracks a solar light source in each of two orthogonal directions.

3. An array of photovoltaic cells, comprising:
an array of optoelectronic components, each optoelectronic component having an end to receive an incident light;
a common electrode electrically connected on an opposite end of selected ones of the optoelectronic components;
at least one DC to AC inverter electrically connected to the common electrode;
at least one biasing electrode connected to each optoelectronic component;
a compound optical structure comprising one or more optical fill materials at the incident end of each optoelectronic component that spatially separates incident light into multiple wavelengths;
wherein each optoelectronic component comprises a P/N junction having a gradient of semiconductor materials and/or dopants responsive to a narrow band of wavelengths.

4. The array of photovoltaic cells of claim 3 further comprising:
each of the one or more optical fill materials having an index of refraction that spatially separates incident light into the narrow band of wavelengths to which the optoelectronic component is responsive.

5. The array of photovoltaic cells of claim 3 further comprising:
a convex lens attached to an outer one of the optical fills materials away from the optoelectronic component, the convex lens focuses incident light onto a central optical axis of each optoelectronic component.

6. The array of photovoltaic cells of claim 3 further comprising:
Group III/V elements as the semiconductor materials.

7. The array of photovoltaic cells of claim 3 further comprising:
a power bus connected to the at least one DC to AC inverter.

8. The array of photovoltaic cells of claim 7 further comprising:
a distribution interface operably connected to the power bus, the power bus also operably connected to the common electrode; and
a digital control operably connected to the distribution interface for distribution of electrical energy generated by the light-to-energy converter.

9. The array of photovoltaic cells of claim 3, further comprising:
a sealed housing containing the array of photovoltaic cells.

10. The array of photovoltaic cells of claim 3, further comprising:
the at least one DC to AC inverter setting one or more electrical parameters of the array of photovoltaic cells.

11. The array of photovoltaic cells of claim 3, further comprising:
the DC to AC inverter, the common electrode, and the optoelectronic components lithographically integrated on a structural substrata.

12. The array of photovoltaic cells of claim 3, further comprising:
the photovoltaic cells arranged in a two-dimensional array.

13. The array of photovoltaic cells of claim 3, further comprising:
the photovoltaic cells arranged in a linear array.

14. The array of photovoltaic cells of claim 4, further comprising:
an orientation of the one or more optical fill materials of the compound optical structure influences spatial separation of the incident light into multiple wavelengths.

15. The array of photovoltaic cells of claim 4, further comprising:
the common electrode and the one or more optical fill materials have compatible thermal expansion and contraction characteristics.

16. The array of photovoltaic cells of claim 4 further comprising the one or more optical fill materials are electrical insulators.

17. The array of photovoltaic cells of claim 6 wherein indium phosphide comprises the semiconductor materials.

18. An array of photovoltaic cells, comprising:
a plurality of optoelectronic components, each having a P/N junction comprising a gradient of optically responsive semiconductor materials and/or dopants, the plurality of optoelectronic components arranged in an array;
a convex lens that focuses incident light toward a central axis of each optoelectronic component;
a plurality of complex optical structures having one or more optical fill materials situated between the convex lens and at a first end of each optoelectronic component, wherein when there are more than one optical fill material, each optical fill material having a different index of refraction than its adjacent optical fill material;
a common electrode structurally integrated with and connecting two or more of the plurality of optoelectronic components at an second end away from the one or more optical fill materials;
a first plurality of optoelectronic components connected at its second end to one plane of the common electrode and a second plurality of optoelectronic components connected at its second end to an opposing plane of the common electrode;
at least one DC to AC inverter electrically connected to and integrated on a same substrata with the common electrode;
wherein the index of refraction and orientation of the at least one optical fill material determine wavelength separation of the incident light and direct the incident light to the optoelectronic components;
and wherein the gradient of optically responsive semiconductor materials and/or dopants of the optoelectronic components have wavelength-specific light biased P/N junctions with band-gaps matching frequencies of the wavelength separated light and convert the light to electrical energy;
and further wherein thermal expansion and contraction of the optical fill material and the common electrode are compatible;
and wherein the at least one DC to AC inverter integrated with the common electrode thermally stabilizes and prevents electrical noise, and converts electrical energy to a controlled AC frequency that is a multiple of a line frequency to which the array is connected.
